(19) United States
(12) Patent Application Publication
(10) Pub. No.: US 2013/0271931 A1
(43) Pub. Date: Oct. 17, 2013

(54) HIGH VOLTAGE TRANSFORMER

(71) Applicants: Jun Hak LEE, Suwon (KR); Hak Soo LEE, Asan-si (KR)

(72) Inventors: Jun Hak LEE, Suwon (KR); Hak Soo LEE, Asan-si (KR)

(21) Appl. No.: 13/462,548

(22) Filed: May 2, 2012

(30) Foreign Application Priority Data
Apr. 13, 2012 (KR) 10-2012-0038358

(51) Int. Cl. H05K 7/14

(52) U.S. Cl. 361/752

(57) ABSTRACT

Provided is a high voltage transformer for outputting a high voltage using AC commercial power as an input in a switching power supply apparatus. The high voltage transformer includes a case, a bobbin, a pair of cores and a voltage distribution PCB. In the case, the inside of the case is subjected to molding treatment in the state in which a bobbin and a voltage distribution PCB are assembled in the case, and a top surface at one side of the case is formed lower than that at the other side of the case so that assembly holes are formed in a center and both sides at the one side of the case. In the bobbin, through-holes are formed in a center and both sides of the bobbin, respectively, and a winding part is formed on an upper outside of the center of the bobbin.

### CROSS REFERENCE

This application claims foreign priority under Paris Convention and 35 U.S.C. §119 to Korean Patent Application No. 10-2012-0038358, filed Apr. 13,2012 with the Korean Intellectual Property Office, the the disclosure of which is hereby incorporated herein by reference in its entirety.

### BACKGROUND OF THE INVENTION

1. Field of the Invention

An aspect of the present invention relates to a high voltage transformer for outputting a high voltage using AC commercial power as an input in a switching power supply apparatus, and more particularly, to a high voltage transformer capable of ensuring stability of high voltage power and outputting a reliable high voltage.

2. Description of the Related Art

If electricity is supplied to an electronic device, a predetermined electronic circuit built in the electronic device is driven to perform a specific function. The power supply unit of the electronic device requires a transformer capable of appropriately transforming a voltage of AC power flowed in the power supply unit to a DC voltage.

A switching transformer is used to generate an appropriate voltage in a secondary coil by controlling the supply of AC commercial power flowed in the transformer through switching. Since the switching transformer is generally designed to obtain a low voltage output, a transformer for obtaining a high voltage output is not commercialized.

Here, the low voltage output is defined as a DC voltage of about 400V or less, and the high voltage output is defined as a DC voltage of about 400V or more.

A high voltage transformer obtains an output by performing a half-wave distribution on a voltage boosted by the transformer using AC commercial power (AC 220/110V) as an input. Here, a voltage distribution circuit used in the high voltage transformer includes passive elements such as capacitors and diodes, which are formed at a secondary coil of the transformer.

A related art high voltage transformer used as described above includes a pair of UU cores formed in an approximately U-shape and adhered opposite to each other, and primary and secondary coils each wound multiple times around a bobbin. The UU cores are coupled to the bobbin around which the primary and secondary coils are wound.

In this case, the degree of voltage boosting is changed depending on the number of winding times of the primary and secondary coils, and a molding treatment is performed on the bobbin so as to increase an internal voltage and to be strong against humidity, etc.

However, in the related art transformer, it is difficult to obtain high voltage power due to breakdown of an internal voltage between the bobbin and the UU cores and breakdown of an internal voltage of the primary and secondary coils wound around the bobbin.

Further, the UU core used in the related art transformer has a lower capacity than another core having the same size, and there is a serious error of inductance (generally designated by L) that becomes a reference value of an output voltage of the high voltage transformer.

That is, as shown in FIG. 1, an air gap 2 is provided between two UU cores 1 so as to prevent saturation of the high voltage transformer, and a space between the two UU cores 1 is formed by the air gap 2. Therefore, when the UU cores 1 are clipped by a clip 3 to fix the UU cores 1, the UU cores 1 are twisted, and therefore, the characteristic of inductance is extremely changed. Further, an adhesive for bonding the UU cores 1 to each other is easily separated from the UU cores 1, or the UU cores 1 are easily damaged.

In the related art high voltage transformer, the UU cores and the bobbin having coils wound therearound are accommodated in a case, and the inside of the case is subjected to molding treatment using an epoxy molding solution. When the UU cores are assembled with the bobbin, the epoxy molding solution is infiltrated into the air gap and cracks of the UU cores, and therefore, there is a problem in producing the high voltage transformer in large quantities due to a change in the inductance of the high voltage transformer.

### SUMMARY OF THE INVENTION

Embodiments of the present invention provide a high voltage transformer having a structure designed to have equal inductance.

Embodiments of the present invention also provide a high voltage transformer for satisfying an internal voltage from DC 15KV to DC 20KV between cores and a bobbin and between primary and secondary coils wound around the bobbin.

Embodiments of the present invention also provide a high voltage transformer having no influence on another circuit by preventing voltage from being exposed to the outside thereof due to a high voltage output.

According to an aspect of the present invention, there is provided a high voltage transformer, including: a case having a hexahedron shape of which bottom is opened, wherein the inside of the case is subjected to molding treatment in the state in which a bobbin and a voltage distribution PCB are assembled in the inside of the case, and a top surface at one side of the case is formed lower than that at the other side of the case so that assembly holes are formed in a center and both sides at the one side of the case, respectively; the bobbin assembled in the inside of the one side of the case, wherein through-holes are formed in a center and both sides of the bobbin, respectively, and a winding part is formed on an upper outside of the center of the bobbin, which the through-hole is formed; a pair of cores assembled at the outside of the case by inserting one of the cores into the assembly holes of the case at the upper portion of the case and inserting the other of the cores into the through-holes of the bobbin at the lower portion of the case; and the voltage distribution PCB assembled in the inside of the other side of the case.

The pair of cores may be EE cores, and an air gap may be formed at a center between the EE cores.

A rectifier circuit composed of capacitors and diodes may be mounted on the voltage distribution PCB and then subjected to the molding treatment.

The lower portion of the bobbin may be formed wider than the upper portion of the bobbin, and the winding part formed on the outside of the bobbin may be vertically divided into a plurality of pieces by a plurality of partition walls.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a view showing UU cores applied to a related art high voltage transformer;

FIG. 2 is an exploded perspective view of a high voltage transformer according to an embodiment of the present invention;

FIG. 3 is a cut-away perspective view of the high voltage transformer assembled in FIG. 2;

FIG. 4 is a sectional view of FIG. 3; and

FIG. 5 is a view showing EE cores applied to the high voltage transformer according to the embodiment of the present invention.

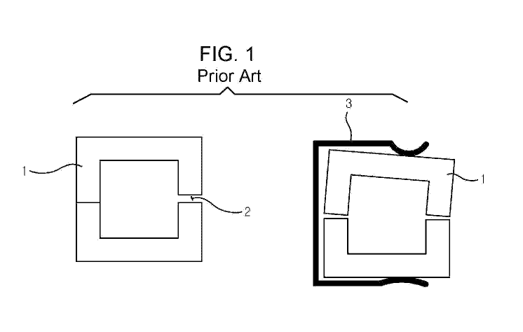

### DETAILED DESCRIPTION OF THE INVENTION

Exemplary embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Like reference numerals refer to like elements throughout.

When a part “includes” a component, if there is no specific opposite statement, it means that the part may further include other components without excluding another component.

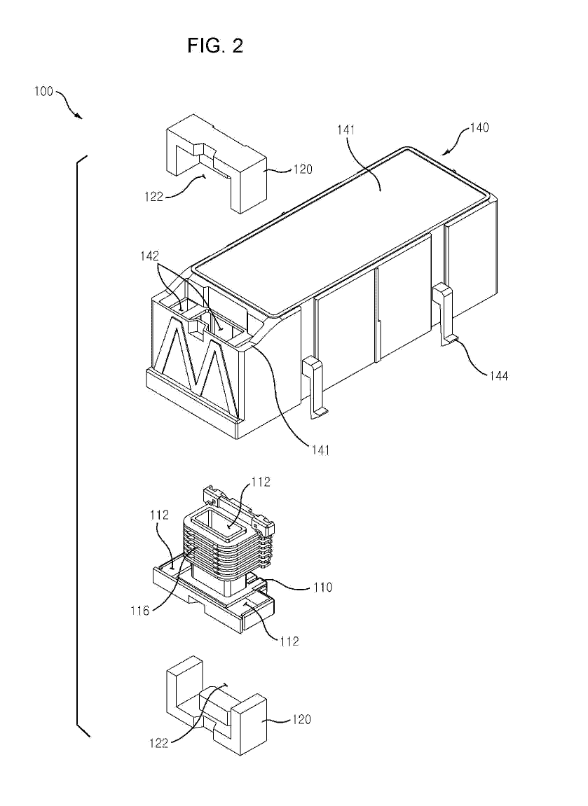

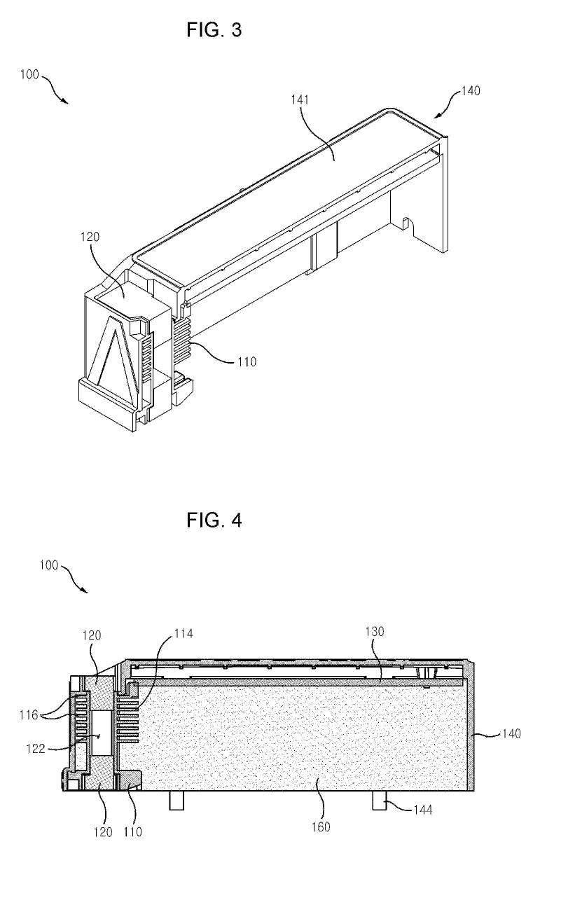

FIG. 2 is an exploded perspective view of a high voltage transformer according to an embodiment of the present invention. FIG. 3 is a cut-away perspective view of the high voltage transformer assembled in FIG. 2. FIG. 4 is a sectional view of FIG. 3.

As shown in these figures, the high voltage transformer 100 includes a bobbin 110, a pair of cores 120, a voltage distribution PCB 130 and a case 140.

The bobbin 110 is made of a synthetic resin that is an insulator, and through-holes 112 are formed in a center and both lower portions of the bobbin 110, respectively.

A winding part 114 is formed on an upper outside of the center of the bobbin 110, in which the through-hole is formed. The winding part 114 is vertically divided into a plurality of pieces by a plurality of partition walls 116.

Accordingly, primary and secondary coils are dividedly wound, thereby reducing the occurrence of eddy current loss.

The lower portion of the bobbin 110 is formed wider than the upper portion of the bobbin 110 so that the bobbin 110 can be stably fixed to a printed circuit board, electronic device, etc.

The case 140 is made of synthetic resin that is an insulator and has a hexahedron shape of which bottom is opened. A top surface 141 at one side of the case 140 is formed lower than that at the other side of the case 140, and assembly holes 142 are respectively formed in a center and both sides at the one side of the case 140 so that the core 120 can be assembled by being inserted into the assembly holes 142.

The voltage distribution PCB 130 is mounted at the other upper portion in the inside of the case 140, in which the through holes 142 are not formed. Thus, the voltage distribution PCB 130 is electrically connected to the coils wound around the bobbin 110.

Latching projections 144 through which the case 140 can be stably fixed to an electronic device, etc. are formed at the outside of the case 140.

A DC voltage is generated by rectifying an AC voltage output from the secondary coil wound around the bobbin 110. In order to generate the DC voltage, a rectifier circuit composed of capacitors and diodes is mounted on the voltage distribution PCB 130, and the AC voltage output from the secondary coil is rectified and distributed, thereby outputting a high voltage.

The bobbin 110 is assembled in the inside of the case 140 by being inserted into the case 140 from the bottom at the one side of the case 140 having the assembly holes 142 formed therein in the state in which the primary and secondary coils are wound around the bobbin 110.

In this case, the assembly holes 142 of the case 140 and the through-holes 112 of the bobbin 110 vertically correspond to each other.

The cores 120 transfer energy of the primary coil to the secondary coil. In the present invention, EE cores having large capacity and high transfer efficiency in the same size as compared with the UU cores of the related art transformer are used as the cores 120.

In the state in which the bobbin 110 is assembled in the inside of the one side of the case 140, one of the EE cores 120 is inserted into the assembly holes 142 at the upper portion of the case 140, and the other of the EE cores 120 is inserted into the through-holes 112 of the bobbin 110 at the lower portion of the case 140. Thus, the EE cores 120 are vertically assembled at the outside of the case 140.

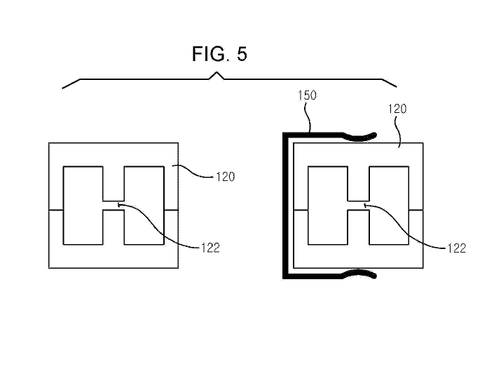

The bobbin 110 and the voltage distribution PCB 130 are assembled in the inside of the case 140, and the EE cores 120 are clipped by a clip 150 (See FIG. 5) so as to bond contact portions between the EE cores 120 to each other in the state in which the EE cores 120 are assembled at the outside of the case 140. Then, the inside of the case 140 is subjected to molding treatment using an epoxy molding solution 160 for the purpose of voltage resistance and humidity resistance.

In the high voltage transformer 100 manufactured as described above, the EE cores 120 assembled at the outside of the case, so that the epoxy molding solution 160 is not infiltrated between the EE cores 120. Thus, it is possible to equalize inductance, to adjust the inductance and to reduce the use of the epoxy molding solution 160.

An insulator is necessarily interposed between the primary and secondary coils so as to ensure a sufficient internal voltage between the primary and secondary coils wound around the winding part 114 of the bobbin 110. In the present invention, the inside of the case 140 is subjected to molding treatment so as to serve as an insulator, so that it is possible to ensure a sufficient internal voltage between the primary and secondary coils.

A primary internal pressure is ensured by performing the molding treatment on the primary and secondary coils wound around the bobbin 110 in the inside of the case 140, and the case 140 is interposed as an insulator between the EE cores 120 and the bobbin 110. Thus, the primary and secondary coils are positioned in the inside of the case 140, and the EE cores 120 are positioned at the outside of the case 140. Accordingly, it is possible to doubly prevent breakdown of the internal voltage.

The rectifier circuit composed of capacitors and diodes is mounted on the voltage distribution PCB 130 and then subjected to the molding treatment, so that it is possible to eliminate influence of another circuit due to the high voltage exposure of the high voltage transformer 100 and to stably output a high voltage.

FIG. 5 is a view showing the EE cores applied to the high voltage transformer according to the embodiment of the present invention.

As shown in FIG. 5, an air gap 122 is formed at a center between the EE cores 120 so as to prevent saturation of the high voltage transformer, and both sides of the EE cores 120 serve as supporters. Thus, the EE cores 120 are not twisted even though the EE cores 120 are clipped by the clip 150 to fix the EE cores to each other. Accordingly, it is possible to have equal inductance and to be strong against an external impact.

As described above, according to the present invention, it is possible to prevent breakdown of the internal voltage between cores and a bobbin and breakdown of the internal voltage between primary and secondary coils wound around the bobbin, to maintain equal inductance using EE cores as ferrite cores, and to mass-produce a high voltage transformer of which structure can be modified.

Although the present invention has been described in connection with the preferred embodiments, the embodiments of the present invention are only for illustrative purposes and should not be construed as limiting the scope of the present invention. It will be understood by those skilled in the art that various changes and modifications can be made thereto within the technical spirit and scope defined by the appended claims.

What is claimed is:

1. A high voltage transformer, comprising:
a case having a hexahedron shape of which bottom is opened, wherein the inside of the case is subjected to molding treatment in the state in which a bobbin and a voltage distribution PCB are assembled in the inside of the case, and a top surface at one side of the case is formed lower than that at the other side of the case so that assembly holes are formed in a center and both sides at the one side of the case, respectively;
the bobbin assembled in the inside of the one side of the case, wherein through-holes are formed in a center and both sides of the bobbin, respectively, and a winding part is formed on an upper outside of the center of the bobbin, which the through-hole is formed;
a pair of cores assembled at the outside of the case by inserting one of the cores into the assembly holes of the case at the upper portion of the case and inserting the other of the cores into the through-holes of the bobbin at the lower portion of the case; and
the voltage distribution PCB assembled in the inside of the other side of the case.

2. The high voltage transformer of claim 1, wherein the pair of cores are EE cores, and an air gap is formed at a center between the EE cores.

3. The high voltage transformer of claim 1, wherein a rectifier circuit composed of capacitors and diodes is mounted on the voltage distribution PCB and then subjected to the molding treatment.

4. The high voltage transformer of claim 1, wherein the lower portion of the bobbin is formed wider than the upper portion of the bobbin, and the winding part formed on the outside of the bobbin is vertically divided into a plurality of pieces by a plurality of partition walls.
